(19) United States
(12) Patent Application Publication
(10) Pub. No.: US 2012/0255610 A1
(43) Pub. Date: Oct. 11, 2012

(54) Encapsulant for Terrestrial Photovoltaic Modules

(76) Inventors: Jayesh Ghewarchand BOKRIA, South Windsor, CT (US); Ryan Terral TUCKER, Simsbury, CT (US)

(21) Appl. No.: 13/441,173

(22) Filed: Apr. 6, 2012

Related U.S. Application Data
(60) Provisional application No. 61/472,710, filed on Apr. 7, 2011.

(51) Int. Cl. H01L 31/0203; F21V 9/06

(52) U.S. Cl. 136/259; 252/589

(57) ABSTRACT

Photovoltaic modules containing solar cells have at least one polymeric optically transparent encapsulant layer with solar energy weighted transmittance at wavelengths of light from 350 to 1200 nanometers equal to or greater than 85% and ultra-violet light cutoff equal to or less than 345 nanometers. The encapsulant material contains at least one olefinic co-polymer having glass transition temperature equal to or less than 20° C. and 10% secant tensile modulus equal to or less than 16,000 psi and at least one ultra-violet light absorber having a chemical structure with no hydroxyl group at an ortho position of an aromatic ring with respect to an aromatic carbonyl group, a triazole group, or a triazine group.

### FIELD OF THE INVENTION

The present invention relates generally to encapsulant material and methods for encapsulating photovoltaic modules (e.g., devices based on crystalline silicon, thin film, etc.). More particularly, the present invention relates to a polymeric optically transparent encapsulant material which optimizes the efficiency of photovoltaic devices while minimizing the deleterious effects of ultra-violet radiation on the polymeric encapsulant.

### BACKGROUND OF THE INVENTION

Electrical energy generating devices, such as photovoltaic modules, are constructed in a modular, multilayered format, typically resulting in a large array of solar panels. The top protective cover (i.e., superstrate) of the individual module may be formed from a transparent material such as glass or polymeric material (e.g., fluoropolymer film) which is disposed on the light-receiving side of the photovoltaic module. The photovoltaic-element layer may be formed from a plurality of electrically interconnected solar cells which are embedded between a first encapsulant layer and a second encapsulant layer. (Thin film devices may contain only one layer of encapsulant material). The encapsulant material is designed to protect the fragile solar cells from mechanical damage, such as cracking or breaking; to adhere to both the top protective cover and the photovoltaic-element layer while accommodating stresses created by differences in thermal expansion coefficients between glass and solar cell; and to provide both internal and external electrical isolation to the photovoltaic-element layer. A lower substrate layer, or backing sheet, completes the layered structure of the photovoltaic module.

Photovoltaic (PV) modules are renewable energy sources that may be used to generate electrical energy directly from solar energy (i.e., sunlight). Light waves from the sun which reach the earth can be divided into infra-red radiation, visible-light radiation, and ultra-violet radiation on the basis of the spectral bandwidth region of the light's wavelength, as measured in nanometers (nm). Since energy is inversely proportional to wavelength with the proportionality constant equal to the product of the Planck's constant and the speed of light in vacuo, the longer the wavelength, the less energetic the radiation is. Terrestrial sunlight contains about 42% infra-red radiation, about 52% visible-light radiation, and about 6% ultra-violet radiation, depending on cloud cover, height above sea level, air mass, and location on earth. Wavelengths of infra-red radiation are typically measured at 700˜15,000 nm; wavelengths of visible-light radiation are typically measured at 400˜700 nm; and wavelengths of ultra-violet radiation are typically measured at 100˜400 nm. Ultra-violet radiation may be further categorized into three different types: long wavelength ultra-violet radiation (UV-A: 315˜400 nm), medium wavelength ultra-violet radiation (UV-B: 280˜315 nm) and short wavelength ultra-violet radiation (UV-C: 100˜280 nm). Since the protective ozone layer in the upper stratosphere filters out most of the harmful UV-C radiation, the ultra-violet radiation component of sunlight which reaches the surface of the earth contains about 95% UV-A radiation and about 5% UV-B radiation. Only radiation with energy equal to or greater than the band gap of the photovoltaic module material can generate an electron-hole pair. In other words, the photovoltaic response of single junction cells is limited to the portion of the sun's spectrum whose energy is above the band gap of the absorbing material. As an example, typical crystalline silicon-based cells have a band gap of around 1.1 eV and can therefore utilize radiation with wavelengths less than 1150 nm. Because the lower energy of far infra-red radiation is difficult for solar cells to utilize effectively, traditional silicon-based, single-junction photovoltaic modules typically generate electrical energy from wavelengths of light from the spectral bandwidth of 280 to 1150 nm.

The encapsulant layer of the photovoltaic module, which is placed between the superstrate and the photovoltaic-element layer, may be formed from organic polymeric materials which are preferably optically transparent in order to ensure that the maximum amount of sunlight is available for use by the photovoltaic-element layer. It is well known, however, that most organic polymeric materials undergo some mode of degradation when exposed to the high energy photons of ultra-violet radiation. The degradation manifests itself, depending on the polymeric material, in yellowing, discoloration, embrittlement, or other loss of physical properties. Discoloration, for example, reduces the amount of solar energy reaching the photovoltaic-element layer of the photovoltaic module and therefore decreases the efficiency of the overall system. Protecting organic polymeric materials from attack by ultra-violet radiation via the addition of ultra-violet light absorbers is also well known in the art. The ultra-violet light absorber functions through its ability to screen out the damaging ultra-violet portion of light due to its high specific absorptivity relative to the polymer. Damage caused by visible light or by heat may be mitigated by the addition of light stabilizers and antioxidants to the polymeric composition.

U.S. Pat. No. 6,093,757, for example, discloses an encapsulating material, useful for photovoltaic devices, which exhibits enhanced photothermal and photochemical stability through the addition of light stabilizers such as bis-(N-octyloxy-tetramethyl)piperidinyl sebacate and antioxidants such as tris(2,4-di-tert-butylphenyl) phosphite to the composition. The patent teaches that light stabilizers neutralize free radicals in the polymeric matrix, while antioxidants inhibit thermal oxidation of the polymer during processing. The patent further teaches that benzophenone-type ultra-violet light absorbers are ineffective at absorbing long wavelength ultra-violet radiation (i.e., greater than 360 nm). The patent therefore recommends the exclusion of all classes of ultra-violet absorbers from encapsulant formulations and includes light stabilizers as a strategy to prevent polymer encapsulant degradation, thereby elongating its service use lifetime.

Different categories of ultra-violet light absorbers provide protection over specific ranges of wavelengths, depending primarily upon the chemical structure of the ultra-violet light absorber in question. 2-Hydroxy-benzophenone-type ultra-violet light absorbers, for example, are able to provide maximum absorption at wavelengths between 300 to 400 nm with increased ultra-violet (UV) absorptivity due to the presence of a hydroxyl group at the second (i.e., ortho) position with respect to an aromatic carbonyl group as well as electron donating substituent(s) on the conjugated aromatic ring structure. These substituents red-shift the absorption, and the 2-hydroxyl group facilitates in dissipating the absorbed energy via a “phenol-enol-type” tautomerism in non-radiative relaxation processes. Thus, the substituents provide the benzophenone-type ultra-violet light absorbers with the ability to absorb UV-A radiation. Since benzophenones absorb a broad spectrum of UV light (i.e., providing the encapsulant with a ultra-violet light cutoff of about 360 nm), the amount of UV light available to the solar cells in the photovoltaic-element layer is undesirably decreased, thus compromising the efficiency of the photovoltaic module. When the UV-cutoff is shifted to the shorter wavelengths (i.e., higher frequency and energy) of ultra-violet radiation, disproportionally more light energy is available for utilization by the solar cells and the electrical generating efficiency of the photovoltaic module is successfully increased.

It is, therefore, an object of this invention to achieve a stable power output over the desired service life of the photovoltaic module by providing a polymeric optically transparent encapsulant which exhibits long-term weathering stability without compromising the optimum efficiency of the underlying solar cells.

### SUMMARY

Polymeric optically transparent encapsulant material containing at least one olefinic co-polymer having a glass transition temperature (Tg) equal to or less than about 20° C. and a 10% secant tensile modulus equal to or less than about 16,000 pounds per square inch (psi) and at least one ultra-violet light absorber having a chemical structure with no hydroxyl group at the second (i.e., ortho) position of an aromatic ring with respect to an aromatic carbonyl group, a triazole group, or a triazine group, and at least one adhesion promoter; wherein the polymeric optically transparent encapsulant material may be characterized by (a) a solar energy weighted transmittance at wavelengths of light from 350 to 1200 nanometers equal to or greater than 85%; and (b) an ultra-violet light cutoff equal to or less than 345 nanometers.

In one embodiment, the at least one olefinic co-polymer may be one or more co-polymers of ethylene and at least one co-monomer including mono-carboxylic acids, di-carboxylic acids, esters of carboxylic acids (including vinyl esters), alkyl acrylates, alpha-olefins, or combinations thereof.

In one embodiment, the at least one ultra-violet light absorber which offers a UV-cutoff equal to or less than 345 nanometers may be benzylidenemalonate-type ultra-violet light absorbers, oxanilide-type ultra-violet light absorbers, or combinations thereof.

The polymeric optically transparent encapsulant may be used in the manufacture of electrical energy generating devices such as photovoltaic modules.

Also disclosed is an electrical energy generating device comprising: (a) an upper protective layer; (b) a middle photovoltaic-element layer; (c) a lower substrate layer; and (d) at least one encapsulant layer having a solar energy weighted transmittance at wavelengths of light from 350 to 1200 nanometers equal to or greater than 85%; and an ultra-violet cutoff light equal to or less than 345 nanometers.

### DETAILED DESCRIPTION

The following definitions apply to the terms as used throughout this specification, unless otherwise limited in specific instances.

When an amount, concentration, or other value or parameter is given as either a range, preferred range, or a list of upper preferable values and lower preferable values, this is to be understood as specifically disclosing all ranges formed from any pair of any upper range limit or preferred value and any lower range limit or preferred value, regardless of whether ranges are separately disclosed. Where a range of numerical values is recited herein, unless otherwise stated, the range is intended to include the endpoints thereof, and all integers and fractions within the range. When the term “about” is used in describing a value or an end-point of a range, the disclosure should be understood to include the specific value or end-point referred to.

As used herein, the singular forms “a,” “an,” and “the” are intended to include the plural forms as well, unless the context transparently indicates otherwise. It will be further understood that the terms “comprises” and/or “comprising,” when used in this specification, specify the presence of stated features, integers, steps, operations, elements, and/or components, but do not preclude the presence or addition of one or more other features.

As used herein, the term “2-hydroxy” or “hydroxyl group in the second position” or “hydroxyl group at the second position” in aromatic molecules designates a hydroxyl functional group connected to an aromatic ring in an ortho position with respect to a carbonyl functional group, a triazole group, or a triazine group that is connected to the same aromatic ring, this terminology thus being in accordance to the IUPAC nomenclature rules where the aromatic carbonyl group, the triazole group, or the triazine group is assigned a greater priority over the hydroxyl functionality.

As used herein, reference to a compound “having a chemical structure with no hydroxyl group at an ortho position of an aromatic ring with respect to an aromatic carbonyl group, a triazole group, or a triazine group” excludes any compound that contains an aromatic ring wherein the aromatic ring is substituted with an aromatic carbonyl group, a triazole group, or a triazine group, and the aromatic ring is further substituted with an hydroxyl group located ortho to one of these groups on the aromatic ring. An “aromatic carbonyl group” is a substituent of the formula —C(═O)Ar wherein Ar is an aromatic group, for example a substituted or unsubstituted phenyl group.

As used herein, the terms “Transmittance” or “T” refer to the fraction of radiant energy that passes through the sample at a given wavelength. In other words, it is the ratio of the intensity (I) of light transmitted by the material to the intensity of incident light impinged on the material, at a particular wavelength (λ). T is often expressed as a percentage and is referred to as “Percent Transmittance” or “% T.” A “Transmission Spectrum” is obtained by measuring T while scanning the required wavelength region relative to air. The following formula may be used to calculate percent transmittance:

%T_{λ}=I(transmitted,λ/I(incident,λ)×100

As used herein, the term “Solar Energy Weighted Transmittance” or “Tₛ” refers to the integral of the spectral transmittance over the standard solar energy distribution in the range between 350 to 1200 nm by normalizing the relative solar energies in the said range so that the sum equals 100 by modifying ASTM E424-71 (2007) to provide a PV-specific irradiance range. Thus, the equation for Tₛ relevant for PV applications is:

Tₛ=Σ_{λ=350 nm}^{λ=1200nm}T_{λ}×E_{λ}

Where T_{λ} is the transmittance measured with a spectrophotometer for the encapsulant layer located adjacent to the top protective cover, as intended in a photovoltaic module, and E_{λ} is the solar energy transmittance using weighted ordinates for 350 to 1200 nm in 50 nm increments and normalized for Σ=100.00 at air mass equal to 2, as provided in ASTM E424-71 (2007). The number is usually expressed as a percentage.

As used herein, the term “Absorbance” or “A” refers to the decadic logarithm of inverse transmittance and which may be calculated by the following formula:

A=−Log₁₀(T)

As used herein, the terms “ultra-violet light cutoff” or “UV-cutoff” refer to the longest wavelength of ultra-violet light at which the Absorbance is greater than or equal to one, or, alternatively, refers to the longest wavelength of ultra-violet light at which percent Transmittance is equal to or less than 10%.

As used herein, the term “phr” refers to parts per hundred of resin, based on the total weight of the olefinic co-polymer used.

As used herein, the term “layer” refers to each of the one or more materials, the same or different, in an essentially planar or planar form, that are secured to one another by any appropriate means, such as by an inherent tendency of the materials to adhere to one another, or by inducing the materials to adhere as by a heating, pressurizing, radiative, chemical, or other appropriate process.

In accordance with the present invention, it has now been found that polymeric optically transparent encapsulant material, containing at least one olefinic co-polymer having a glass transition temperature (Tg) equal to or less than about 20° C. and a 10% secant tensile modulus equal to or less than about 16,000 pounds per square inch (psi) and containing at least one ultra-violet light absorber having a chemical structure with no hydroxyl group at the second (ortho) position of an aromatic ring with respect to an aromatic carbonyl group, a triazole group, or a triazine group exhibits (a) solar energy weighted transmittance at wavelengths of light from 350 to 1200 nanometers equal to or greater than 85%, preferably equal to or greater than 90%; and (b) ultra-violet light cutoff equal to or less than 345 nanometers.

It has been surprisingly and unexpectedly discovered that no significant encapsulant discoloration occurs when a larger amount of UV-A radiation is made available to the underlying solar cells contained in the photovoltaic module. Discoloration of plastic material is typically measured as a yellowness index (YI) using arbitrary units (a.u.), as determined in accordance with ASTM D1925-70. Some yellowing may be measured, but the discoloration is due to the inherent nature of ultra-violet absorbers (i.e., by the reduction in transmission of the shorter wavelengths of light), rather than symptomatic of polymeric degradation. The effect is not noticeable to human observers (without the aid of instrumentation) until a yellowness index of about 10 a.u. is reached. Efficiency of solar cells is compromised when the front side of the encapsulant material adjacent to the top protective cover darkens or yellows due to UV- or thermal-induced degradation. Because the development of YI relates to the absorption tail in the visible region (i.e., greater than 400 nm), laboratory studies show that UV-induced degradation with YI of 10 units can result in a decrease of solar energy weighted transmittance through the encapsulant material of about 1%, which in turn may reduce electrical output by about 1%. An encapsulant material having a YI of 20 may decrease solar energy weighted transmittance by about 3%. When the shorter wavelengths of UV-B radiation are absorbed while the longer wavelengths of UV-A radiation are transmitted through the upper encapsulant layer, the power output of the solar cells is improved without sacrificing the desired service life of the encapsulant.

In accordance with the present invention, the at least one olefinic co-polymer used herein may have a glass transition temperature (Tg) equal to or less than about 20° C. to maintain good adhesion and impact resistance for the photovoltaic module. The glass transition temperature may be measured through any known art method, for example, test method ASTM D3418-08 as determined by dynamic mechanical analysis (DMA), where Tg is defined as the temperature for a maximum value of Tangent delta at the same temperature region that the storage modulus decreases from the glassy state to the rubbery state. Preferably, the olefinic co-polymer of the present invention may have a glass transition temperature equal to or less than about 10° C., or more preferably, equal to or less than about −5° C. but typically greater than −150° C. In one embodiment of the present invention, the olefinic co-polymer used herein has a Tg equal to or less than −10° C. but greater than −100° C. Higher or lower glass transition temperatures may be possible, depending on the requirements of the encapsulating material.

In accordance with the present invention, the at least one olefinic co-polymer used herein may have a 10% secant tensile modulus equal to or less than about 16,000 psi to afford good physical shock protection for the photovoltaic module. The 10% secant tensile modulus may be measured through any known art method, for example, test method ASTM D638-10. Preferably, the olefinic co-polymer of the present invention may have a 10% secant tensile modulus equal to or less than about 14,500 psi, or more preferably, equal to or less than about 12,000 psi.

In one or more embodiments of the present invention, the at least one olefinic co-polymer is preferably an ethylene-based co-polymer with one or more co-monomers characterized by ethylene content greater than 40 percent (%), preferably from 45% to 98%, and more preferably from 50% to 95%. Co-monomers suitable for use in olefinic co-polymers of the present invention may include mono- or di-carboxylic acids, vinyl esters of carboxylic acids, alkyl acrylates, alpha-olefins, or combinations thereof.

In one or more embodiments, the at least one olefinic co-polymer of the present invention may be one or more ethylene co-polymers containing at least one mono- or di-carboxylic acid co-monomer. Suitable mono- or di-carboxylic acid co-monomers include acrylic, methacrylic, ethacrylic, itaconic, maleic, fumaric, crotonic, cinnamic, or combinations thereof. In addition, one or more alkyl acrylate co-monomers, such as acrylate, methylacrylate, methyl-methacrylate, butylacrylate, isobutylacrylate, or combinations thereof, may be included in the co-polymer of the present invention. Ethylene mono- or di-carboxylic acid co-polymers include, but are not limited to, ethylene/acrylic acid, ethylene/methacrylic acid, ethylene/acrylic acid/methylacrylate, ethylene/acrylic acid/n-butylacrylate, ethylene/acrylic acid/is obutylacrylate, ethylene/acrylic acid/n-butylmethacrylate, ethylene/acrylic acid/methyl-methacrylate, ethylene/methacrylic acid/methylacrylate, ethylene/methacrylic acid/n-butylmethacrylate, ethylene/methacrylic acid/is obutylacrylate, ethylene/methacrylic acid/methyl methacrylate, or combinations thereof. Exemplary ethylene mono- or di-carboxylic acid co-polymers are commercially available as Nucrel® from Du Pont de Nemours & Co., in Wilmington, Del.; as Escor® from ExxonMobil Chemical Co., in Houston, Tex.; and as Primacor® from Dow Chemical Co., in Midland, Mich.

In one or more embodiments, the at least one olefinic co-polymer of the present invention may be one or more ethylene vinyl ester co-polymers which are radically, or high pressured, polymerized to obtain vinyl ester content from 10% to 45%, preferably from 15% to 40%. Ethylene vinyl ester co-polymers include, but are not limited to, ethylene vinylformate, ethylene vinylacetate, ethylene vinylpropionate, ethylene vinylisopropionate, ethylene vinylbutyrate, ethylene vinylhexanoate, or combinations thereof. Ethylene vinylacetate is preferred. The ethylene vinyl ester co-polymer typically has a melt flow rate (as determined by ASTM D1238-10) at a temperature of 190° C. and at a load of 2.16 kg) ranging from about 0.01 dg/min to about 120 dg/min, preferably from about 0.1 dg/min to about 100 dg/min, and more preferably from about 1 dg/min to about 80 dg/min. The ethylene vinyl ester co-polymer is preferably further characterized by a density typically ranging from about 0.89 g/cm³ to about 1.25 g/cm³, preferably from about 0.905 g/cm³ to about 1.05 g/cm³, and more preferably from about 0.91 g/cm³ to about 0.99 g/cm³. Exemplary ethylene vinyl ester co-polymers are commercially available as Evatane® from Arkema, Inc., in Philadelphia, Pa.; as Elvax® from Du Pont de Nemours & Co., in Wilmington, Del.; as Escorene® from ExxonMobil Chemical Co., in Houston, Tex.; and as Ateva® from Celanese EVA Performance Polymers, in Edmonton, Canada.

In one or more embodiments, the at least one olefinic co-polymer of the present invention may be ethylene alkyl acrylate co-polymers which are radically, or high-pressured, polymerized to obtain alkyl acrylate content from 10% to 45%, preferably from 15% to 40%. Alkyl acrylates suitable for use in the co-polymer of the present invention include C1-C8 alkyl esters of acrylic acid, for example, the methyl, ethyl, butyl, isobutyl, hexyl, and 2-ethylhexyl esters. Ethylene alkyl acrylate co-polymers include, but are not limited to, ethylene methylacrylate, ethylene ethylacrylate, ethylene butylacrylate, ethylene methyl-methacrylate, ethylene ethyl-methacrylate, or combinations thereof. Ethylene copolymers with methyl (meth)acrylate, ethyl (meth)acrylate, and butyl (meth)acrylate are preferred. As used herein, the term “(meth)acrylate” refers to either methacrylate or acrylate. The ethylene alkyl acrylate co-polymer typically has a melt flow rate (as determined by ASTM D1238-10) at a temperature of 190° C. and at a load of 2.16 kg) ranging from about 0.01 dg/min to about 100 dg/min, preferably from about 0.1 dg/min to about 75 dg/min, and more preferably from about 1 dg/min to about 50 dg/min. The ethylene alkyl acrylate co-polymer is preferably further characterized by a density typically ranging from about 0.88 g/cm³ to about 1.05 g/cm³, preferably from about 0.905 g/cm³ to about 0.98 g/cm³, and more preferably from about 0.91 g/cm³ to about 0.97 g/cm³. Exemplary ethylene alkyl acrylate co-polymers are commercially available as Elvaloy® from Du Pont de Nemours & Co., in Wilmington, Del.; as Optema® from ExxonMobil Chemical Co., in Houston, Tex.; as Lotryl® from Arkema Inc., in Philadelphia, Pa.; EMAC® and EBAC® from Westlake Chemicals, in Longview, Tex.; and as Amplify® from Dow Chemical Co., in Midland, Mich.

In one or more embodiments, the at least one olefinic co-polymer of the present invention may be ethylene alpha-olefin co-polymers which are catalyzed via metallocene, or single site, catalysis to obtain alpha-olefin content from 1% to 50%, preferably from 3% to 45%. Alpha-olefin co-monomers suitable for use in the co-polymer of the present invention include any C₃ to C₂₀ olefin, with propylene, 1-butene, 1-hexene, 1-octene, or 4-methyl-1-pentene being most preferred. The alpha-olefin co-monomers may be linear or branched, and two or more comonomers may be used, if desired. The metallocene-catalyzed ethylene alpha-olefin co-polymer typically has a melt flow rate (as determined by ASTM D1238-10) at a temperature of 190° C. and at a load of 2.16 kg) ranging from about 0.01 dg/min to about 120 dg/min, preferably from about 0.05 dg/min to about 100 dg/min, and more preferably from about 1 dg/min to about 50 dg/min The metallocene-catalyzed ethylene alpha-olefin co-polymer is preferably further characterized by a density typically ranging from about 0.84 g/cm³ to about 1.05 g/cm³, preferably from about 0.845 g/cm³ to about 0.98 g/cm³, and more preferably from about 0.85 g/cm³ to about 0.95 g/cm³. Exemplary ethylene alpha-olefin co-polymers are commercially available as Engage®, Versify®, or Affinity® from Dow Chemical Co., in Midland, Mich.; as Exact® or Exceed® from ExxonMobil Chemical Co., in Houston, Tex.; and as Tafmer® from Mitsui Chemical Inc., in Tokyo, Japan.

In one or more embodiments, the at least one olefinic co-polymer of the present invention may be blended with a second polymeric component. As used herein, the term “blended” refers to either an in-situ reactor-made blend (i.e., using a series of reactors while polymerization is occurring), a physical blend (i.e., using internal mixers, static mixers, impingement mixers, solution blending, melt blending with single or twin screw extruders, lateral 2-roll mixers, etc.), or combinations thereof. The second polymeric component may be one or more cycloolefin co-polymers which are prepared with the aid of transition-metal catalysts by co-polymerizing cycloolefin homopolymers with additional co-monomers. Cycloolefins are mono or polyunsaturated polycyclic ring systems, such as cycloalkenes, bicycloalkenes, tricycloalkenes, or tetracycloalkenes. The ring systems can be monosubstituted or polysubstituted. Preference is given to the cycloolefins which are built up from monoalkylated or unsubstituted cycloolefins. Particularly preferred cycloolefin homopolymers are polynorbornene, polycyclopentene, polydimethyloctahydronaphthalene, and poly(5-methyl)norbornene. In a preferred embodiment, cycloolefin co-polymers contain up to 30%, preferably 1% to 25% of co-monomer. Preferred co-monomers are olefins having 2 to 6 carbon atoms, in particular ethylene, butylene, or combinations thereof. Preferred cycloolefin co-polymers of the invention are ethylene-norbornene co-polymers. The cycloolefin co-polymer typically has a melt flow rate (as determined by ASTM D1238-10) at a temperature of 260° C. and at a load of 2.16 kg ranging from about 0.01 dg/min to about 105 dg/min, preferably from about 0.1 dg/min to about 95 dg/min, and more preferably from about 1 dg/min to about 80 dg/min The cycloolefin co-polymer is preferably further characterized by a density typically ranging from about 0.905 g/cm³ to about 1.35 g/cm³, preferably from about 0.95 g/cm³ to about 1.25 g/cm³, and more preferably from about 0.97 g/cm³ to about 1.20 g/cm³. The preferred cycloolefin co-polymer of the present invention has a Tg equal to or greater than 40° C., preferably from 55° C. to 300° C. Exemplary cycloolefin co-polymers are commercially available as Topas® from Topas Advanced Polymers GmbH, in Frankfurt, Germany; as Zeonex® or Zeonor® from Zeon Chemicals, in Tokyo, Japan; and as Apel® from Mitsui Chemical Inc., in Tokyo, Japan.

In accordance with the present invention, the at least one ultra-violet light absorber used herein typically exhibits a chemical structure which does not have a hydroxyl group at the second (i.e., ortho) position of the aromatic ring with respect to an aromatic carbonyl group, a triazole group, or a triazine group to facilitate any radiative or non-radiative relaxation processes upon excitement. The contribution to the electronics from the substituents on the conjugated system thus provides the polymeric optically transparent encapsulant characterized by (a) solar energy weighted transmittance at wavelengths of light from 350 to 1200 nanometers equal to or greater than 85%; and (b) ultra-violet light cutoff equal to or less than 345 nanometers. The at least one ultra-violet light absorber is preferably an oxanilide-type ultra-violet light absorber, benzylidenemalonate-type ultra-violet light absorber, or combinations thereof.

Since the chemical structure of the benzophenone-type ultra-violet light absorbers exhibit at least one hydroxyl group at the second position (i.e., ortho) of its aromatic ring with respect to an aromatic carbonyl group, benzophenone-type ultra-violet light absorbers are excluded from the composition of the present invention. Typical examples of the benzophenone-type ultra-violet light absorbers which are excluded from the present invention are 2,4-dihydroxybenzophenone, 2-hydroxy-4-methoxybenzophenone, 2-hydroxy-4-octoxybenzophenone, 2-hydroxy-4-dodecyloxybenzophenone, 2,2′-dihydroxy-4-methoxybenzophenone, 2,2′-dihydroxy-4,4′-dimethoxybenzophenone, 2-hydroxy-4-methoxy-5-sulfobenzophenone, and bis(2-methoxy-4-hydroxy-5-benzophenone)methane.

Since the chemical structure of the 2-hydroxybenzotriazole-type ultra-violet light absorbers exhibit at least one hydroxyl group at the second position of a phenyl ring in ortho-position to the benzotriazole moiety, 2-hydroxybenzotriazole-type ultra-violet light absorbers are excluded from the composition of the present invention. Typical examples of the 2-hydroxybenzotriazole-type ultra-violet light absorbers which are excluded from the present invention are 2-(2-hydroxy-5-tert-octylphenyl)benzotriazole, 2-(2′-hydroxy-5′-methylphenyl)benzotriazole, 2-(2′-hydroxy-5′-tert-butylphenyl)benzotriazole, and 2-(2′-hydroxy-3′-tert-butyl-5-methylphenyl)-5-chlorobenzotriazole.

Since the chemical structure of 2-hydroxyphenyl triazine-type ultra-violet light absorbers exhibit at least one hydroxyl group at the second position of the phenyl ring in ortho-position to the triazine moiety, 2-hydroxyphenyltriazine-type ultra-violet light absorbers are excluded from the composition of the present invention. Typical examples of the 2-hydroxyphenyl triazine-type ultra-violet light absorbers which are excluded from the present invention are 244-[(2-Hydroxy-3-dodecyloxypropyl)oxy]-2-hydroxyphenyl]-4,6-bis(2,4-dimethylphenyl)-1,3,5-triazine and 2-[4-[(2-Hydroxy-3-tridecyloxypropyl)oxy]-2-hydroxyphenyl]-4,6-bis(2,4-dimethylphenyl)-1,3,5-triazine.

Accordingly, oxanilide-type ultra-violet light absorbers of the present invention are of the formula (I)

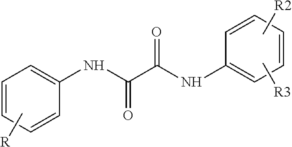

where

R is straight or branched chain alkyl of 1 to 24 carbon atoms, straight or branched chain alkoxy of 1 to 24 carbon atoms, straight or branched chain alkenyl of 2 to 18 carbon atoms, cycloalkyl of 5 to 12 carbon atoms, phenylalkyl of 7 to 15 carbon atoms, aryl of 6 to 12 carbon atoms, or said aryl or said phenylalkyl is substituted on the aryl ring by 1 to 4 alkyl of 1 to 4 carbon atoms

R2 and R3 are independently hydrogen, cyano, nitro, -D1, —CO-D1, —COOD1, —CONHD1, —CON(D1)₂, where D1 is hydrogen, straight or branched chain alkyl of 1 to 24 carbon atoms, straight or branched chain alkenyl of 2 to 18 carbon atoms, cycloalkyl of 5 to 12 carbon atoms, straight or branched chain alkoxy of 1 to 24 carbon atoms, phenylalkyl of 7 to 15 carbon atoms, aryl of 6 to 12 carbon atoms, or said aryl or said phenylalkyl substituted on the aryl ring by 1 to 4 alkyl of 1 to 4 carbon atoms and where neither R, R2, nor R3 is an hydroxyl group at the second position (i.e., ortho) of the aromatic ring. Thus the oxanilide-type ultra-violet light absorbers of formula (I) do not include a hydroxyl group at a position on an aromatic ring that is ortho to an aromatic carbonyl group containing substituent, a triazole group, or a triazine group.

Accordingly, benzylidenemalonate-type ultra-violet light absorbers of the present invention include compounds of formula (II)

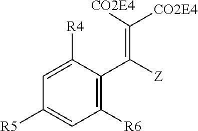

where

R4, R5 and R6 are independently hydrogen, straight or branched chain alkyl of 1 to 24 carbon atoms, straight or branched chain alkoxy of 1 to 24 carbon atoms, straight or branched chain alkenyl of 2 to 18 carbon atoms, cycloalkyl of 5 to 12 carbon atoms, phenylalkyl of 7 to 15 carbon atoms, aryl of 6 to 12 carbon atoms, or said aryl or said phenylalkyl substituted on the aryl ring by 1 to 4 alkyl of 1 to 4 carbon atoms, or said alkyl, alkoxy, or alkenyl substituted by one or more —OH, —COOE4, —OCOE4, —OE1, —NHCOE4, —NE2E3 groups, or mixtures thereof, where E1 is straight or branched chain alkyl of 1 to 24 carbon atoms or straight or branched chain alkenyl of 2 to 18 carbon atoms and where neither R4, R5, nor R6 is an hydroxyl group at the second position (i.e., ortho) of the aromatic ring with respect to an aromatic carbonyl group, a triazole group, or a triazine group;

Z is independently hydrogen, straight or branched chain alkyl of 1 to 24 carbon atoms, phenyl or phenyl substituted by 1 to 4 straight or branched chain alkyl of 1 to 4 carbon atoms, straight or branched chain alkoxy of 1 to 12 carbon atoms, or said alkyl or alkoxy substituted by one or more —OH, —COOE4, —OCOE4, —OE1, —NHCOE4;

E2 and E3 are independently hydrogen, alkyl of 1 to 18 carbon atoms, aryl of 6 to 14 carbon atoms, aralkyl of 7 to 15 carbon atoms, straight or branched chain alkenyl of 2 to 18 carbon atoms, cycloalkyl of 5 to 12 carbon atoms, or hydroxylalkyl of 1 to 3 carbon atoms, or E2 and E3 together with the N atom are a pyrrolidine, piperidine, piperazine or morpholine ring; and

E4 is hydrogen, straight or branched chain alkyl of 1 to 24 carbon atoms which may be substituted by 1 to 4 hydroxyl groups, cycloalkyl of 5 to 12 carbon atoms, straight or branched chain alkenyl of 3 to 18 carbon atoms, or said alkyl, cycloalkyl, or alkenyl substituted by one or more —NE5E6 groups, or mixtures thereof, where E5 and E6 are independently hydrogen, alkyl of 1 to 18 carbon atoms, aryl of 6 to 14 carbon atoms, aralkyl of 7 to 15 carbon atoms, straight or branched chain alkenyl of 2 to 18 carbon atoms, cycloalkyl of 5 to 12 carbon atoms, or hydroxylalkyl of 1 to 3 carbon atoms, phenylalkyl of 7 to 15 carbon atoms, aryl of 6 to 12 carbon atoms, or said aryl or said phenylalkyl substituted on the aryl ring by 1 to 4 alkyl of 1 to 4 carbon atoms, or E5 and E6 together with the N atom are a pyrrolidine, piperidine, piperazine or morpholine ring.

The at least one ultra-violet light absorber may include, but is not limited to, 2-ethyl-2′-ethoxy-oxalanilide (CAS No. 23949-66-8); N-(2-ethoxyphenyl)-N-(4-isododecylphenyl) oxamide (CAS No. 82493-14-9); tetra-ethyl-2,2′-(1,4-phenylene-dimethylidene)-bismalonate (CAS No. 6337-43-5); dimethyl-4-methoxybenzylidenemalonate (CAS No. 7443-25-6); bis(1,2,2,6,6-pentamethylpiperidin-4-yl) p-methoxybenzylidenemalonate (CAS No. 147783-69-5); or combinations thereof. The at least one ultra-violet light absorber may be used at a level of about 0.01 phr to about 1.85 phr, or preferably, about 0.01 phr to about 1.55 phr, based on the total weight of the olefinic co-polymer used. Exemplary ultra-violet light absorbers are commercially available as Tinuvin® from BASF SE, in Ludwigshafen, Germany; as Hostavin® from Clariant International, in Muttenz, Switzerland; and as Cyasorb® from Cytec Industries, in Woodland Park, N.J.

The at least one ultra-violet light absorber may include 2,4-di-tert-butylphenyl-4′-hydroxy-3′,5′-di-tert-butyl benzoate (CAS 4221-80-1), which has a hydroxy group para to the aromatic carbonyl group, or hexadecyl-3,5-di-t-butyl-4-hydroxybenzoate (CAS 67845-93-6), which also has a hydroxy group para to the aromatic carbonyl group.

One or more of a variety of conventional additives may also be optionally, but preferably, included in one or more of the encapsulant layers of the present invention as suggested by the intended use of the known additive material, and the guidance provided herein coupled with the knowledge and experience of those of ordinary skill in the art. In one or more embodiments, one or more additives may be included in one or more encapsulant layers to improve optical properties. In one or more embodiments, one or more additives may be included in one or more encapsulant layers to improve mechanical properties. In one or more embodiments, one or more additives may be included in one or more encapsulant layers to improve adhesive properties. In one or more embodiments, one or more additives may be included in one or more encapsulant layers to improve thermal conductivity properties. Such additives may include one or more colorants, pigments, mineral fillers, metal oxides, adhesion promoters, surface active agents, curing agents, curing co-agents, thermal stabilizers, ultra-violet light stabilizers, antioxidants, processing aids, plasticizers, flame retardants, reinforcing agents, anti-static agents, dispersants, and the like, or combinations thereof. These are preferably independently selected depending on the other materials present in a given encapsulant layer and the desired or selected characteristics of that layer in the final photovoltaic module.

Suitable adhesion promoters which are useful in the present invention to enhance adhesion between the encapsulant layer or layers and the photovoltaic-element layer(s) and/or adhesion to one or more of other components comprising the photovoltaic module including but not limited to superstrate(s), substrate(s), electrical components such as cell-ribbons, bus-bars, etc., cell coatings such as anti-reflective layer(s), metallization layer(s), insulation layer(s), passivation layer(s), solder points and/or locations, or dielectric or holding materials including but not limited to pressure sensitive cell-holding adhesive tapes, etc., include, but are not limited to, organosilanes containing at least one vinyl group such as vinyl-triethoxysilane, vinyl-tris(beta-methoxyethoxy)silane, etc.; organosilanes containing at least one methacryl group such as 3-methacryloxypropyl-trimethoxysilane, etc.; organosilanes containing at least one epoxy group such as 3-glycidoxypropyl-trimethoxysilane, 3-glycidoxypropyl-triethoxysilane, etc.; organosilanes containing at least one amino group such as 3-aminopropyl-trimethoxysilane, vinylbenzylaminoethylaminopropyl-trimethoxysilane, N-beta-(aminoethyl)-gamma-aminopropyl-trimethoxysilane, etc.; organosilanes containing at least one mercapto group such as 3-mercaptopropyl-trimethoxysilane, etc.; chlorosilanes such as 3-chloropropyl-methoxysilane, vinyl-trichlorosilane, etc.; or combinations thereof. These adhesion promoters may be used at a level equal to or less than 1.45 phr, or preferably, about 0.01 phr to about 1.05 phr, based on the total weight of the olefinic co-polymer used. Exemplary adhesion promoters are commercially available as Silquest® from Momentive Performance Materials, in Waterford, N.Y.; as Dynasylan® from Evonik Degussa GmbH, in Frankfurt, Germany; and as the Z-series organosilanes from Dow Corning, in Midland, Mich. Other examples of adhesion promoters include acrylate- and blocked isocyanate-based compositions. A specific example of a commercially available blocked isocyanate-based composition is Nourybond® from Air Products and Chemicals, Inc., in Allentown, Pa.

Suitable surface active agents useful in the present invention include, but are not limited to, wetting agents, surfactants, defoamers, silicone fluids, coupling agents, sulfates, sulfonates, fatty acids, fluoro-compounds, silicon-containing compounds and their derivatives, or combinations thereof. These surface active agents may be used at a level equal to or less than 1.45 phr, or preferably, about 0.001 phr to about 0.90 phr, based on the total weight of the olefinic co-polymer used. Exemplary surface active agents are commercially available as Fluorad® from 3M Company, in St. Paul, Minn.; as Zonyl® from Du Pont de Nemours & Co., in Wilmington, Del.; as CoatOSil® or Silwet® from Momentive Performance Materials, in Waterford, N.Y.; as silicone surfactants from BYK Chemie GmbH, in Wesel, Germany; as silicone-based wetting agents or as polyalkylene oxide polysiloxanes from Dow Corning, in Midland, Mich.; as polyalkylene oxide polysiloxanes from Shin-Etsu Chemical Company, in Tokyo, Japan; and as polyether siloxane copolymers from Evonik Tego Chemie GmbH, in Essen, Germany.

Suitable curing agents useful in the present invention include, but are not limited to, phenolic resins, organic peroxides, maleimides, sulfur-containing curatives, and silicon-containing curatives. The specific curing agent selected for a particular composition will depend on various considerations, including decomposition temperature and kinetics, cost, volatility, and storage longevity. The purpose of the curing agent is to cross-link the polymer during the lamination procedure, thus providing a thermoset material which is mechanically stable at typical operating temperatures. The degree of chemical cross-linking of the cured encapsulant, generally referred to as “gel content,” is expressed as the fraction (percentage) of the polymer that cannot be extracted using a suitable solvent, such as toluene or tetrahydrofuran. To provide sufficient mechanical strength to support the solar cells in a photovoltaic module, the gel content of the encapsulant must be at least 70%. The requisite gel content is achieved during the lamination and curing cycles of module processing, typically by adjusting time and temperature conditions during the lamination procedure. Radical-producing curing agents such as organic peroxides having a decomposition half-life of less than about one hour at 140° C. are preferred. Half life is defined as the time required, at a specific temperature, to reduce the original peroxide concentration by half.

Suitable organic peroxide curing agents useful in the present invention include, but are not limited to, dialkyl peroxides such as di-t-butyl peroxide; dicumyl peroxide; t-butylcumyl peroxide; alpha,alpha'-bis(t-butylperoxy-m-isopropyl)benzene; alpha,alpha'-bis(t-butylperoxy)diisopropylbenzene; 2,5-dimethyl-2,5-bis(t-butylperoxy)hexane; 2,5-dimethyl-2,5-bis(t-butylperoxy)-hexyne-3, etc.; diacyl peroxides such as acetyl peroxide; isobutyryl peroxide; octanoyl peroxide; decanoyl peroxide; lauroyl peroxide; 3,5,5-trimethylhexanoyl peroxide; benzoyl peroxide; 2,4-dichlorobenzoyl peroxide; m-toluoyl peroxide, etc.; peroxyketals such as 1,1-bis(t-butylperoxy)-3,3,5-trimethylcyclohexane; 1,1-bis(t-hexylperoxy)-3,3,5-trimethylcyclohexane; 1,1-bis(t-butylperoxy)cyclohexane; 2,2-bis(t-butylperoxy) octane; 1,1-bis(t-hexylperoxy)cyclohexane; 2,2-bis(4,4,-di-(t-butylperoxy)cyclohexyl)propane; n-butyl-4,4-bis(t-butylperoxy)butane; n-butyl-4,4-bis(t-butylperoxy)valerate, etc.; peroxyesters such as t-butyl peroxyacetate; t-butyl peroxyisobutyrate; t-butyl peroxybenzoate; t-butylperoxy-2-ethylhexyl carbonate; t-butyl peroxymaleate; t-butyl peroxyisoproyl carbonate; t-amylperoxy-2-ethylhexyl carbonate; t-hexylperoxy isopropyl carbonate; cumyl peroxyoctate, etc.; hydroperoxides such as t-butyl hydroperoxide; cumene hydroperoxide; diisopropylbenzene hydroperoxide; 2,5-dimethylhexane-2,5-dihydroperoxide; 1,1,3,3-tetra-methylbutyl peroxide, etc; or combination thereof. Preferred organic peroxide curing agents are 2,5-dimethyl-2,5-bis(t-butylperoxy)hexane; 1,1-bis(t-butylperoxy)-3,3,5-trimethylcyclohexane; 2,2-bis(4,4,-di-(t-butylperoxy)cyclohexyl)propane; t-amylperoxy-2-ethylhexyl carbonate; t-hexylperoxy isopropyl carbonate; or t-butylperoxy-2-ethylhexyl carbonate. These curing agents may be used at a level equal to or less than 3.05 phr, or preferably, about 0.01 phr to about 2.85 phr, based on the total weight of the olefinic co-polymer used. Exemplary organic peroxide curing agents are commercially available as Varox® from R.T. Vanderbilt Co., in Norwalk, Conn.; as Trigonox® from Akzo Nobel N.V., in Amsterdam, the Netherlands; and as Luperox® from Arkema, Inc., in Philadelphia, Pa.

The polymeric optically transparent encapsulant of the present invention is useful in forming one or more layers in photovoltaic modules. A typical photovoltaic module has a transparent upper protective layer or layers that faces upward and is exposed to the sun. A middle photovoltaic-element layer is positioned beneath the upper protective layer(s). The middle photovoltaic-element layer may contain a plurality of solar cells electrically interconnected in a series-parallel configuration in a conventional manner to provide a suitable output voltage for the photovoltaic array. The middle photovoltaic-element layer rests on a lower substrate layer(s). The middle photovoltaic-element layer is secured to the lower substrate layer by a lower adhesive layer formed from a polymeric encapsulant material. The lower adhesive layer may contain pigments, fillers, or combinations thereof to improve the functional properties of the encapsulant. The middle photovoltaic-element layer is secured to the upper protective layer by an upper adhesive layer formed from the polymeric optically transparent encapsulant. The middle photovoltaic-element layer is thus encapsulated between the lower adhesive layer and the upper adhesive layer.

The upper protective layer provides impact protection as well as weather protection to the photovoltaic module. The upper protective layer is advantageously formed from glass, preferably tempered, patterned, or both, such as Solite® patterned glass, commercially available from AGC Solar, in Brussels, Belgium. Fluorinated polymers which are formed into thin films in a suitable thickness may also be used as the upper protective layer(s). Exemplary fluorinated polymers are commercially available as Teflon® or Tefzel® from Du Pont de Nemours & Co., in Wilmington, Del.; as Kynar® from Arkema Inc., in Philadelphia, Pa.; and as Fluon® from Asahi Glass Co., in Tokyo, Japan. The upper protective layer may have a thickness equal to or greater than 0.25 millimeters (mm). Thus, the solar cells in the middle photovoltaic-element layer are exposed to direct sunlight without being exposed to moisture and other climatic conditions and without being exposed to direct impact by falling objects and debris. The lower substrate layer is typically formed from glass or a layered polymeric construct. The layered polymeric structure typically has an outermost layer formed from fluoropolymer film such as Tedlar®, commercially available from Du Pont de Nemours & Co., in Wilmington, Del.; as Hylar®, commercially available from Solvay Solexis, in Bollate, Italy; as Aclar®, commercially available from Honeywell International, Inc., in Morristown, N.J.; as Kynar®, commercially available from Arkema Inc., in Philadelphia, Pa.; and/or as fiber reinforced plastic, such as polyester resin embedded with stranded glass fibers. The lower substrate layer provides an advantageous combination of stiffness, light weight, very low permeability, electrical isolation, and flatness.

Preferably, the lower adhesive layer is provided as a thin film having a thickness typically between 0.05 to 2.5 mm, preferably between 0.05 to 1.3 mm, or more preferably between 0.1 to 1.1 mm that is positioned on the upper surface of the lower substrate layer. The array of solar cells in the middle photovoltaic-element layer is then positioned on the lower adhesive layer. The upper adhesive layer is placed over the middle photovoltaic-element layer so that the solar cells are sandwiched between the two adhesive layers. The transparent upper protective layer is then positioned over the upper transparent adhesive layer to complete the laminated structure. Lamination is generally defined as the process of bonding together two or more prefabricated sheet or film layers by the use of adhesives, or by a combination of heat and pressure (i.e., melt-pressing). The polymeric encapsulant acts as a binder to secure the solar cells between the upper protective layer and the lower substrate layer and as a cushion between the two outer layers.

### Examples

The invention is further defined by reference to the following examples, describing the polymeric optically transparent encapsulant material of the present invention. It will be apparent to those of ordinary skill in the art that many modifications, both to materials and methods, may be practiced without departing from the purpose and intent of this invention based on the description herein. Thus, the following examples are offered by way of illustration, and not by way of limitation, to describe in greater detail certain methods for the preparation, treatment, and testing of some polymeric optically transparent encapsulant material of the invention.

Several encapsulant compositions were prepared and then compared to evaluate the performance of the compositions as encapsulants for photovoltaic modules or thin film devices. The components utilized in the compositions are listed in Table 1.

TABLE 1

| | |
|---|---|
| ethylene vinylacetate-1 | 33% VA; Tg: −20° C. |
| ethylene vinylacetate-2 | 28% VA; Tg: −20° C. |
| UV-1 | dimethyl-4-methoxybenzylidenemalonate |
| UV-2 | 2-hydroxy-4-methoxybenzophenone |
| UV-3 | 2-hydroxy-4-octoxy benzophenone |
| light stabilizer | bis(2,2,6,6,-tetramethyl-4-piperidyl)sebacate |
| adhesion promoter | 3-methacryloxypropyltrimethoxysilane |
| surface active agent | poly(oxyethylene•oxypropylene) methyl |
| | polysiloxane |

Three-inch-square pieces of encapsulant material were formulated, based on the compositions shown in Table 2 and with the addition of sufficient peroxide, such as t-butylperoxy-2-ethylhexyl carbonate, to achieve gel content in toluene equal to or greater than 70% under a particular thermal cure (lamination) condition. Using two- to three-inch-square pieces of patterned Solite® solar glass, two-layer and three-layer constructs were formed with the encapsulant material, depending on the requirements of the test procedure. All encapsulant samples were homogenous in formulation, free of any contaminants, inclusions, etc., while being comparable and uniform in thickness of about 0.46 mm of the encapsulant layer. The solar glass was a non-cerium containing and low-iron glass available from AGC Solar with a UV-cutoff of about 300 nm and a thickness of about 3.2 mm. For the two-layered constructs, three-inch-square pieces of encapsulant material were placed on the patterned Solite® solar glass such that the encapsulant was in contact with the heavily textured side of the glass. The glass-encapsulant assembly was placed between two polytetrafluoroethylene (PTFE) coated release sheets to produce a planar and defect-free encapsulant surface for presentation to the spectrophotometer after lamination. For the three-layered constructs, three-inch-square pieces of encapsulant material were sandwiched between two three-inch-square pieces of patterned Solite® solar glass. The encapsulant and glass assembly was carefully placed in a clam-shell vacuum laminator and laminated under a platen temperature set-point of 143.3° C. with 3 minutes of evacuation cycle followed by a 9-minute press cycle. As expected from thermally cured systems based on heat activated and decomposed radical initiators such as t-butylperoxy-2-ethylhexyl carbonate, longer cycle times and/or higher temperatures results in higher gel contents for a given formulation with fixed peroxide concentration. This is a direct result of higher peroxide decomposition and greater amounts of radicals available for polymer crosslinking/curing reactions. For a platen set point of 143.3° C. and under a total 12 minute cycle, measured gel contents were between 75 and 81% using a toluene-soak method. Thus, the cycle chosen above resulted in the desired gel content of greater than or equal to 70%. The samples were then removed and allowed to completely cool to room temperature and conditioned in the dark under ambient laboratory conditions for either 4 to 12 hours (for UV-cutoff testing) or 24 hours (for measuring accelerated aging).

TABLE 2

| | | | | | Comp. |
|---|---|---|---|---|---|
| | | | | | Ex. 2 |
| | Ex. 1 & | Ex. 2 & | | Comp. Ex. 1 & | & Comp. |
| | Ex. 4 | Ex. 5 | Ex. 3 | Comp. Ex. 3 | Ex. 4 |
| ethylene | 100 | 100 | 100 | 0 | 100 |
| vinylacetate-1 | | | | | |
| (phr) | | | | | |
| ethylene | 0 | 0 | 0 | 100 | 0 |
| vinylacetate-2 | | | | | |
| (phr) | | | | | |
| UV-1 (phr) | 0.3 | 0.1 | 0.1 | 0 | 0 |
| UV-2 (phr) | 0 | 0 | 0 | 0 | 0.3 |
| UV-3 (phr) | 0 | 0 | 0 | 0.3 | 0 |
| light stabilizer | 0 | 0 | 0 | 0 | 0.1 |
| adhesion | 0.25 | 0.25 | 0.25 | 0.25 | 0.25 |
| promoter | | | | | |
| (phr) | | | | | |
| surface | 0 | 0 | 0.05 | 0 | 0 |
| active agent | | | | | |
| (phr) | | | | | |

### Test Procedure I. Accelerated Aging

Initial yellowness index (YI) was measured in accordance to ASTM D1925-70. YI is a leading indicator of photothermal-related chemical events occurring in polymeric systems since the first indications of degradation in polymeric properties is typically a change in color (i.e., increased yellowness). Three-layered glass-encapsulant-glass constructs were exposed under conditions of nominal black panel temperature equal to about 90° C. and about 50% RH, with lamp irradiance of 0.55 W/m² at 340 nm and a lower-end UV-cutoff of about 285 nm in the rotating carousel of a Xenon-Arc weather-o-meter for two week exposure cycles. These conditions impose UV radiation equal to approximately two suns, and correspond to acceleration factors equal to about one year of field exposure for every week of accelerated Xenon-Arc weather-o-meter exposure. At the end of each cycle, the sample was removed, allowed to equilibrate to ambient conditions, visually evaluated, and a YI measurement acquired using a BYK-Gardner spectro-guide 45/0 gloss portable spectrophotometer in accordance to ASTM D1925-70 standard and routinely calibrated per manufacturer's recommendations via white block and green block reference standards. After evaluation and measurements, the sample specimen was reintroduced into the Xenon-Arc weather-o-meter chamber for the next two week cycle. Table 3 presents results of the evaluation, representing the equivalent of thirty years of service in the field.

TABLE 3

| | | | | Comp. | Comp. |
|---|---|---|---|---|---|
| Time | Ex. 1 | Ex. 2 | Ex. 3 | Ex. 1 | Ex. 2 |
| (weeks) | YI (a.u.) | YI (a.u.) | YI (a.u.) | YI (a.u.) | YI (a.u.) |
| 0 | 0.26 | 1.20 | 0.47 | 1.24 | 0.56 |
| 2 | 2.30 | 1.65 | 3.17 | 2.23 | 2.07 |
| 4 | 1.21 | 1.75 | 4.56 | 2.14 | 2.71 |
| 6 | 1.51 | 2.58 | 3.74 | 2.70 | 2.81 |
| 8 | 2.65 | 2.46 | 3.17 | 3.73 | 2.90 |
| 10 | 2.81 | 2.20 | 3.40 | 3.46 | 3.19 |
| 12 | 2.64 | 3.03 | 3.81 | 4.08 | 6.03 |
| 14 | 2.41 | 2.46 | 3.89 | 4.19 | 5.78 |
| 16 | 2.68 | 2.41 | 3.17 | 3.54 | 9.59 |
| 18 | 2.81 | 2.88 | 3.12 | 4.00 | 8.98 |
| 20 | 2.65 | 2.51 | 3.71 | 4.26 | 9.30 |
| 22 | 3.98 | 2.61 | 2.89 | 5.17 | 9.01 |
| 24 | 3.04 | 2.41 | 3.29 | 3.64 | 10.12 |
| 26 | 3.08 | 2.71 | 3.11 | 3.98 | 9.16 |
| 28 | 2.90 | 4.64 | 3.21 | 4.96 | 10.03 |
| 30 | 3.18 | 3.48 | 3.05 | 3.50 | 9.48 |

Ex. 1, Ex. 2, and Ex. 3, exemplary compositions of the present invention, surprisingly and unexpectedly showed little or no polymeric degradation, as evidenced by the low level of discoloration, over the entire accelerated weathering cycle. The samples were visibly clear, without any noticeable haze, bubbles, signs of delamination, and no changes in physical appearance were apparent to the unaided eye when compared to the original. The results clearly show that blocking the effects of UV-B radiation, rather than blocking both UV-A and UV-B radiation, provide adequate protection against discoloration during the accelerated aging cycle. Comp. Ex. 1, containing a 2-hydroxybenzophenone-type ultra-violet light absorber, shows similar results. Based on these findings, UV-A radiation causes little or no damage to the encapsulant material. It has been surprisingly and unexpectedly shown that allowing UV-A radiation to pass through the encapsulant layer to the underlying solar cells, and therefore improving the efficiency of the photovoltaic module, will not be detrimental to the encapsulant layer. Comp. Ex. 2, containing a 2-hydroxybenzophenone-type ultra-violet light absorber and a light stabilizer, showed a gradual increase in yellowness during accelerated aging during the period allotted. At the end of the experiment, the sample showed a discoloration that was nearly visible to a human observer. Without being bound by theory, the results for Comp. Ex. 2 may have been created by an antagonistic effect between the UV-A absorber and the light stabilizer. Careful experimentation is required to achieve the proper balance when combinations of light stabilizers and ultra-violet light absorbers are used However, Ex. 1, Ex. 2, and Ex. 3 contained no light stabilizer component.

### Test Procedure II. Ultra-Violet Light Cutoff

Measurements of percent transmittance (% T), as determined by transmission optical spectroscopy in the UV-Vis-NIR region, may be used to calculate both Solar Energy Weighted Transmittance and UV-cutoff A PerkinElmer LAMBDA 1050 UV-Vis-NIR double beam spectrophotometer equipped with a 150 mm Labsphere Spectralon integrating sphere and a PMT/InGaAs detector combination module operating under transmission mode and corrected for empty-sphere (air) baseline was used to acquire % T data. The two-layered glass-encapsulant construct was presented to the spectrophotometer's integrating sphere such that the monochromatic incident beam first impinges on solar glass and then on the encapsulant before proceeding to the detectors, thereby mimicking the light path in an photovoltaic module where the photovoltaic-element layer (solar cells) is substituted by the 150 mm integrating sphere. Transmission spectrophotometric measurements were made in 1 nm increments from 250 nm to 1400 nm. The “empty-cell” (air) 100% T baseline measurement was refreshed every hour to negate any potential drifts in the instrument baseline. Table 4 presents some of the results of the evaluation.

TABLE 4

| | Ex. 4 | Ex. 5 | Comp. Ex. 3 | Comp. Ex. 4 |
|---|---|---|---|---|
| Wavelength | Transmission | Transmission | Transmission | Transmission |
| (nm) | (%) | (%) | (%) | (%) |
| 1100 | 90.84 | 91.18 | 91.21 | 91.54 |
| 1000 | 90.80 | 91.13 | 91.19 | 91.50 |
| 900 | 90.72 | 91.05 | 91.12 | 91.42 |
| 800 | 91.09 | 91.39 | 91.28 | 91.70 |
| 700 | 91.21 | 91.44 | 91.39 | 91.79 |
| 600 | 91.15 | 91.45 | 91.28 | 91.75 |
| 500 | 90.85 | 91.18 | 90.99 | 91.49 |
| 400 | 88.61 | 89.64 | 87.12 | 87.77 |
| 395 | 88.07 | 89.25 | 85.04 | 85.60 |
| 390 | 87.35 | 88.53 | 81.54 | 81.78 |
| 385 | 86.36 | 87.50 | 75.59 | 75.51 |
| 380 | 85.29 | 86.17 | 66.48 | 65.61 |
| 375 | 84.05 | 84.35 | 52.60 | 50.86 |
| 370 | 82.58 | 81.83 | 37.09 | 34.59 |
| 365 | 80.39 | 77.68 | 21.30 | 18.68 |
| 360 | 77.00 | 72.06 | 9.55 | 7.55 |
| 355 | 71.58 | 64.82 | 3.22 | 2.19 |
| 350 | 62.84 | 56.60 | 0.89 | 0.48 |
| 345 | 48.93 | 48.31 | 0.23 | 0.10 |
| 340 | 30.75 | 40.83 | 0.08 | 0.03 |
| 335 | 14.23 | 34.06 | 0.06 | 0.03 |
| 330 | 5.23 | 28.31 | 0.06 | 0.04 |
| 325 | 1.91 | 23.61 | 0.07 | 0.05 |
| 320 | 0.82 | 19.49 | 0.09 | 0.08 |
| 315 | 0.43 | 15.42 | 0.12 | 0.10 |
| 310 | 0.29 | 11.27 | 0.14 | 0.12 |
| 305 | 0.23 | 7.06 | 0.16 | 0.15 |
| 300 | 0.18 | 3.55 | 0.19 | 0.19 |
| 295 | 0.12 | 1.42 | 0.22 | 0.20 |
| 290 | 0.11 | 0.59 | 0.25 | 0.25 |
| 285 | 0.11 | 0.40 | 0.29 | 0.27 |
| 280 | 0.14 | 0.40 | 0.31 | 0.31 |

The results clearly show the differences in UV-cutoff between encapsulant material containing UV-A absorbers (i.e., Comp. Ex. 3 and Comp. Ex. 4) and encapsulant material containing UV-B absorbers (i.e., Ex. 4 and Ex. 5). The 2-hydroxybenzophenone-type ultra-violet light absorber present in Comp. Ex. 3 and Comp. Ex. 4 were excellent candidates for broad spectrum protection against all types of terrestrial UV radiation, but were not useful in encapsulant formulations of the present invention since the UV-cutoff was greater than 360 nm. UV-B absorbers (i.e., Ex. 4 and Ex. 5), which were transparent to the broad UV-A radiation region while effectively blocking UV-B radiation, shifted the UV-cutoff of the encapsulant to the shorter wavelengths of light to less than 345 nm, thus providing a larger amount of solar energy to be utilized by photovoltaic modules for improved power output and overall efficiency. Although measurements were collected continuously from 250 to 1400 nm, the data in Table 4 was selected to highlight the difference in properties of UV-A and UV-B absorbers and to focus on the effect compositions containing either UV-A or UV-B absorbers had on the encapsulant material. Raw data was used to calculate both Solar Energy Weighted Transmittance (Tₛ) for PV-specific irradiance range and the specific UV-cutoff by mathematically evaluating the optical transmittance data as obtained from the UV-Vis-NIR spectrometer. The specific UV-cutoff was determined using the raw data that was available in 1 nm intervals. The UV-cutoff for Ex. 4 was 333 nm, while the UV-cutoff for Ex. 5 was 308 nm. The UV-cutoff for Comp. Ex. 3 was 360 nm, while the UV-cutoff of Comp. Ex. 4 was 361 nm. Tₛ was calculated by using transmission data between 350 to 1200 nm using data points in 50 nm intervals in conjunction with the solar energy transmittance weighted ordinates, at air mass equal to 2, in 50 nm increments, normalized for Σ=100.00 between the limits of 350 to 1200 nm, as provided in ASTM E424-71 (2007). The Tₛ for Ex. 4 was 90.23%, while the Tₛ for Ex. 5 was 90.48%. The Tₛ for Comp. Ex. 3 was 89.53%, while the Tₛ for Comp. Ex. 4 was 89.95%. These results are summarized in Table 5 below.

TABLE 5

| | Ex. 4 | Ex. 5 | Comp. Ex. 3 | Comp. Ex. 4 |
|---|---|---|---|---|
| UV-Cutoff | 333 | 308 | 360 | 361 |
| Wavelength (nm) | | | | |
| Tₛ (%) | 90.23 | 90.48 | 89.53 | 89.95 |

It is particularly important to note that the Tₛ calculations used in this invention did not include the transmittance data below 350 nm, where there is a marked increase in transmittance. Although terrestrial solar energy below 350 nm is available for very effective use by solar cells via increased blue response, and not used for Tₛ determination, a distinguishable increase in Tₛ is found. The absolute increase of terrestrial solar flux available to the photovoltaic-element layer in wavelengths longer than 350 nm ranged from about 0.3% (absolute) to about 1.0% (absolute). The actual increase is logically and expectedly greater. Because of the hypsochromic shift in UV-cutoff, the solar energy weighted transmission of Ex. 4 and Ex. 5 is higher when compared to either Comp. Ex. 3 or Comp. Ex. 4.

All publications, patents and patent applications cited in this specification are herein incorporated by reference, and for any and all purposes, as if each individual publication, patent or patent application were specifically indicated to be incorporated by reference. In the case of inconsistencies, the present disclosure will prevail.

The foregoing description illustrates and describes the present disclosure. Additionally, the disclosure shows and describes only the preferred embodiments of the disclosure, but, as mentioned above, it is to be understood that it is capable of changes or modifications within the scope of the concept as expressed herein, commensurate with the above teachings and/or skill or knowledge of the relevant art. The embodiments described hereinabove are further intended to explain best modes known of practicing the invention and to enable others skilled in the art to utilize the disclosure in such, or other, embodiments and with the various modification required by the particular applications or uses disclosed wherein. Accordingly, the description is not intended to limit the invention to the form disclosed herein. Also, it is intended that the appended claims be construed to include alternative embodiments.

What is claimed is:

1. Polymeric optically transparent encapsulant composition comprising:
at least one olefinic co-polymer having a glass transition temperature equal to or less than 20° C. and a 10% secant tensile modulus equal to or less than 16,000 psi,
at least one ultra-violet light absorber having a chemical structure with no hydroxyl group at an ortho position of an aromatic ring with respect to an aromatic carbonyl group, a triazole group, or a triazine group, and
at least one adhesion promoter;
wherein the polymeric optically transparent encapsulant is characterized by:
(a) a solar energy weighted transmittance at wavelengths of light from 350 to 1200 nanometers equal to or greater than 85%; and
(b) an ultra-violet light cutoff equal to or less than 345 nanometers.

2. Encapsulant composition of claim 1, wherein the at least one ultra-violet light absorber has the general formula 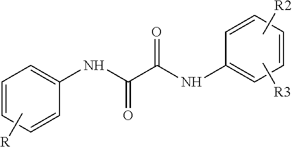
wherein
R is a straight or branched chain alkyl of 1 to 24 carbon atoms, straight or branched chain alkoxy of 1 to 24 carbon atoms, straight or branched chain alkenyl of 2 to 18 carbon atoms, cycloalkyl of 5 to 12 carbon atoms, phenylalkyl of 7 to 15 carbon atoms, aryl of 6 to 12 carbon atoms, or said aryl or said phenylalkyl is substituted on the aryl ring by 1 to 4 alkyl of 1 to 4 carbon atoms,
R2 and R3 are independently hydrogen, cyano, nitro, -D1, —C0-D1, —COOD1, —CONHD1, —CON(D1)₂, where D1 is hydrogen, straight or branched chain alkyl of 1 to 24 carbon atoms, straight or branched chain alkenyl of 2 to 18 carbon atoms, cycloalkyl of 5 to 12 carbon atoms, straight or branched chain alkoxy of 1 to 24 carbon atoms, phenylalkyl of 7 to 15 carbon atoms, aryl of 6 to 12 carbon atoms, or said aryl or said phenylalkyl is substituted on the aryl ring by 1 to 4 alkyl of 1 to 4 carbon atoms, and where neither R, R2, nor R3 is a hydroxyl group at the ortho position of the aromatic ring.

3. The encapsulant composition of claim 1, wherein the at least one ultra-violet light absorber has the general formula 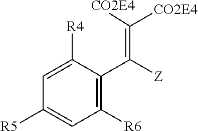
wherein
R4, R5 and R6 are independently hydrogen, straight or branched chain alkyl of 1 to 24 carbon atoms, straight or branched chain alkoxy of 1 to 24 carbon atoms, straight or branched chain alkenyl of 2 to 18 carbon atoms, cycloalkyl of 5 to 12 carbon atoms, phenylalkyl of 7 to 15 carbon atoms, aryl of 6 to 12 carbon atoms, or said aryl or said phenylalkyl is substituted on the aryl ring by 1 to 4 alkyl of 1 to 4 carbon atoms, or said alkyl, alkoxy, or alkenyl is substituted by one or more —OH, —COOE4, —OCOE4, —OE1, —NHCOE4, —NE2E3 groups, or mixtures thereof, where E1 is straight or branched chain alkyl of 1 to 24 carbon atoms or straight or branched chain alkenyl of 2 to 18 carbon atoms;
Z is independently hydrogen, straight or branched chain alkyl of 1 to 24 carbon atoms, phenyl or phenyl substituted by 1 to 4 straight or branched chain alkyl of 1 to 4 carbon atoms, straight or branched chain alkoxy of 1 to 12 carbon atoms, or said alkyl or alkoxy is substituted by one or more —OH, —COOE4, —OCOE4, —OE1, —NHCOE4;
E2 and E3 are independently hydrogen, alkyl of 1 to 18 carbon atoms, aryl of 6 to 14 carbon atoms, aralkyl of 7 to 15 carbon atoms, straight or branched chain alkenyl of 2 to 18 carbon atoms, cycloalkyl of 5 to 12 carbon atoms, or hydroxylalkyl of 1 to 3 carbon atoms, or E2 and E3 together with the N atom are a pyrrolidine, piperidine, piperazine or morpholine ring; and
E4 is hydrogen, straight or branched chain alkyl of 1 to 24 carbon atoms which may be substituted by 1 to 4 hydroxyl groups, cycloalkyl of 5 to 12 carbon atoms, straight or branched chain alkenyl of 3 to 18 carbon atoms, or said alkyl, cycloalkyl, or alkenyl is substituted by one or more —NE5E6 groups, or mixtures thereof, where E5 and E6 are independently hydrogen, alkyl of 1 to 18 carbon atoms, aryl of 6 to 14 carbon atoms, aralkyl of 7 to 15 carbon atoms, straight or branched chain alkenyl of 2 to 18 carbon atoms, cycloalkyl of 5 to 12 carbon atoms, or hydroxylalkyl of 1 to 3 carbon atoms, phenylalkyl of 7 to 15 carbon atoms, aryl of 6 to 12 carbon atoms, or said aryl or said phenylalkyl is substituted on the aryl ring by 1 to 4 alkyl of 1 to 4 carbon atoms, or E5 and E6 together with the N atom are a pyrrolidine, piperidine, piperazine or morpholine ring.

4. Encapsulant composition of claim 1, wherein the at least one olefinic co-polymer comprises a co-polymer of ethylene and at least one co-monomer comprising mono-carboxylic acids, di-carboxylic acids, vinyl esters of carboxylic acids, alkyl acrylates, alpha-olefins, or combinations thereof.

5. Encapsulant composition of claim 4, wherein the at least one olefinic co-polymer comprises ethylene vinylformate, ethylene vinylacetate, ethylene vinylpropionate, ethylene vinylisopropionate, ethylene vinylbutyrate, ethylene vinylhexanoate, or combinations thereof.

6. Encapsulant composition of claim 4, wherein the at least one olefinic co-polymer comprises at least one metallocene catalyzed ethylene alpha-olefin co-polymer.

7. Encapsulant composition of claim 1, wherein the at least one adhesion promoter comprises an organosilane adhesion promoter containing at least one group amenable to chain-growth polymerization which is at least one vinyl group, at least one methacryl group, at least one acryl group, at least one epoxy group, at least one amino group, or at least one mercapto group; a chlorosilane adhesion promoter; or combinations thereof.

8. Encapsulant composition of claim 7, wherein the at least one adhesion promoter comprises vinyl-trimethoxysilane, vinyl-triethoxysilane, vinyl-tris(beta-methoxyethoxy)silane, 3-methacryloxypropyl-trimethoxysilane, 3-glycidoxypropyl-trimethoxysilane, 3-glycidoxypropyl-triethoxysilane, 3-aminopropyl-trimethoxysilane, vinylbenzylaminoethylaminopropyl-trimethoxysilane, N-beta-(aminoethyl)-gamma-aminopropyl-trimethoxysilane, 3-mercaptopropyl-trimethoxysilane, 3-chloropropyl-methoxysilane, vinyl-trichlorosilane, oligomeric-methoxysilane, oligomeric-ethoxysilane, or combinations thereof.

9. Encapsulant composition of claim 1, wherein the composition comprises the ultra-violet light absorber in the range of about 0.01 phr to about 1.85 phr and comprises the adhesion promoter in the range of equal to or less than 1.45 phr, based on the total weight of the olefinic co-polymer used.

10. Encapsulant composition of claim 1, further comprising one or more colorants, pigments, mineral fillers, metal oxides, curing agents, curing co-agents, adhesion promoters, thermal stabilizers, ultra-violet light stabilizers, antioxidants, processing aids, plasticizers, flame retardants, reinforcing agents, anti-static agents, dispersants, or combinations thereof.

11. Encapsulant composition of claim 10, wherein the curing agent comprises an organic peroxide curing agents having a decomposition half-life of less than about one hour at 150° C.

12. Encapsulant composition of claim 11, wherein the curing agent comprises 2,5-dimethyl-2,5-bis(t-butylperoxy)hexane; 1,1-bis(t-butylperoxy)-3,3,5-trimethylcyclohexane; 2,2-bis(4,4,-di-(t-butylperoxy)cyclohexyl)propane; t-amylperoxy-2-ethylhexyl carbonate; t-hexylperoxy isopropyl carbonate; t-butylperoxy-2-ethylhexyl carbonate, or combinations thereof.

13. Encapsulant composition of claim 11, wherein the composition comprises the curing agent in the range of equal to or less than 3.05 phr, based on the total weight of the olefinic co-polymer used.

14. Electrical energy generating device comprising:
(a) an upper protective layer;
(b) a middle photovoltaic-element layer;
(c) a lower substrate layer; and
(d) at least one encapsulant layer having a solar energy weighted transmittance at wavelengths of light from 350 to 1200 nanometers equal to or greater than 85%; and an ultra-violet cutoff light equal to or less than 345 nanometers.

15. Electrical energy generating device of claim 14, wherein the at least one encapsulant layer comprises:
(a) at least one olefinic co-polymer having a glass transition temperature equal to or less than 20° C. and a 10% secant tensile modulus equal to or less than 16,000 psi;
(b) at least one ultra-violet light absorber having a chemical structure with no hydroxyl group at an ortho position of an aromatic ring with respect to an aromatic carbonyl group, a triazole group, or a triazine group; and
(c) at least one adhesion promoter.
